(19) United States
(12) Patent Application Publication
(10) Pub. No.: US 2026/0253557 A1
(43) Pub. Date: Aug. 27, 2026

(54) DISPLAY PANEL AND DISPLAY DEVICE INCLUDING THE SAME

(71) Applicant: LG Display Co., Ltd., Seoul (KR)

(72) Inventor: Karam KIM, Gimpo-si (KR)

(21) Appl. No.: 19/419,693

(22) Filed: Dec. 15, 2025

(30) Foreign Application Priority Data
Feb. 27, 2025 (KR) 10-2025-0025838

(51) Int. Cl. G09G 3/3275; G09G 3/3233; G09G 3/32

(52) U.S. Cl. CPC G09G 3/3275; G09G 3/3233; G09G 3/32; G09G 2300/0819; G09G 2300/0842; G09G 2300/0861; G09G 2310/08; G09G 2320/0233; G09G 2320/041; G09G 2330/021

(57) ABSTRACT

A display device includes: a display panel comprising a plurality of pixels each including a plurality of sub-pixels, a plurality of data lines connected to each of the sub-pixels, and a plurality of reset voltage lines to which a reset voltage for initializing light-emitting elements included in the respective sub-pixels is configured to be applied; a data driver configured to transmit a data voltage to each of the sub-pixels through the data lines; and a power supply configured to supply a first reset voltage to a plurality of first reset voltage lines among the plurality of reset voltage lines, and to supply a second reset voltage different from the first reset voltage to a plurality of second reset voltage lines among the plurality of reset voltage lines.

### CROSS REFERENCE TO RELATED APPLICATION

This application claims priority from and the benefit of Korean Patent Application No. 10-2025-0025838, filed on February 27, 2025, which is hereby incorporated by reference for all purposes as if fully set forth herein.

### BACKGROUND

### FIELD

Embodiments of the invention relate generally to a display panel and a display device including the same, and more particularly, to a display panel, which compensates for luminance fluctuations due to heat generation in a portion of a display panel, and a display device including the same.

### DISCUSSION OF THE BACKGROUND

Image display devices that display various information on a screen are evolving toward thinner, lighter, more portable, and higher performance. Accordingly, lightweight and slim display devices are attracting attention.

Examples of such flat panel display devices include a liquid crystal display (LCD) device, an organic light emitting diode (OLED) display device, a micro light emitting diode (LED) display device, a quantum dot display device, etc.

Among these displays, the OLED display device gaining popularity as a means of miniaturizing a device and displaying vivid colors without requiring a separate light source has advantages such as fast response speed, a high contrast ratio, luminous efficiency, luminance, a wide viewing angle, and the like using a self-emissive OLED.

In addition, the display device can include an OLED disposed in each of a plurality of sub-pixels arranged on a display panel and display an image by controlling a driving current flowing through the OLED to cause each sub-pixel to emit light.

However, in an organic light-emitting display, luminance non-uniformity may occur in certain regions of the display panel due to heat generated by a driving circuit. Accordingly, there is a need to improve image quality by reducing luminance deviations of the display panel caused by heat generation from the data driver.

The above information disclosed in this Background section is only for understanding of the background of the inventive concepts, and, therefore, it may contain information that does not constitute prior art.

### SUMMARY

Display panels and display devices including the same according to embodiments of the invention are capable of varying a magnitude of a reset voltage based on temperature without increasing the number of reset voltage lines applied to a plurality of sub-pixels disposed on the display panel.

In addition, an embodiment of the invention is directed to providing a display panel that is capable of applying a reset voltage lower than a reset voltage applied to other areas of the display panel, to an area of the display panel in which a data driver is disposed.

In addition, an embodiment of the invention is directed to providing a display panel having a plurality of additional reset voltage lines, to which a reset voltage for initializing light-emitting elements included in respective sub-pixels disposed around a data driver is applied.

In addition, an embodiment of the invention is directed to providing a display panel on which a first reset voltage line, to which a first voltage for initializing sub-pixels in a peripheral area where a data driver is disposed is applied, and a second reset voltage line, to which a second voltage for initializing sub-pixels in a remaining area excluding the peripheral area is applied, are arranged.

Additional features of the inventive concepts will be set forth in the description which follows, and in part will be apparent from the description, or may be learned by practice of the inventive concepts.

According to one or more embodiments of the invention, a display device includes: a display panel comprising a plurality of pixels each including a plurality of sub-pixels, a plurality of data lines connected to each of the sub-pixels, and a plurality of reset voltage lines to which a reset voltage for initializing light-emitting elements included in the respective sub-pixels is configured to be applied; a data driver configured to transmit a data voltage to each of the sub-pixels through the data lines; and a power supply configured to supply a first reset voltage to a plurality of first reset voltage lines among the plurality of reset voltage lines, and to supply a second reset voltage different from the first reset voltage to a plurality of second reset voltage lines among the plurality of reset voltage lines.

The plurality of first reset voltage lines may be disposed in a remaining area of the display panel excluding a peripheral area of the data driver, the plurality of second reset voltage lines may be disposed in the peripheral area of the data driver, and the second reset voltage may be lower than the first reset voltage.

The first reset voltage may be a voltage for compensating for each of the plurality of sub-pixels electrically connected to the first reset voltage lines.

The second reset voltage may be a voltage for compensating for each of the plurality of sub-pixels electrically connected to the second reset voltage lines, and the second reset voltage may be determined based on a temperature resulting from heat generation of the data driver.

The second reset voltage may decrease as the temperature resulting from heat generation of the data driver increases, and may increase as the temperature resulting from the heat generation of the data driver decreases.

The plurality of second reset voltage lines may include, among the plurality of reset voltage lines, a predetermined number of reset voltage lines disposed above the data driver and a predetermined number of reset voltage lines disposed below the data driver.

According to one or more embodiments of the invention, a display device includes: a display panel comprising a plurality of pixels each including a plurality of sub-pixels, a plurality of data lines connected to each of the sub-pixels, and a plurality of reset voltage lines to which a reset voltage for initializing light-emitting elements included in the respective sub-pixels is configured to be applied; and a data driver configured to transmit a data voltage to each of the sub-pixels through the data lines. The display panel further includes a plurality of additional reset voltage lines, and a reset voltage is configured to be applied to the plurality of additional reset voltage lines to initialize light-emitting elements of the plurality of sub-pixels disposed in a peripheral area of the data driver.

The display device may further include a power supply circuit configured to apply a first voltage to the plurality of reset voltage lines and apply a second voltage different from the first voltage to the plurality of additional reset voltage lines.

The plurality of reset voltage lines may be disposed to extend across a substantially entire region of the display panel, and the plurality of additional reset voltage lines may be disposed in the peripheral area of the data driver.

The plurality of additional reset voltage lines may be disposed in upward, downward, leftward, and rightward directions with respect to the data driver and may include a predetermined number of reset voltage lines.

The second voltage applied through the plurality of additional reset voltage lines may be lower than the first voltage.

The second voltage may be configured to be lower as the temperature resulting from heat generation of the data driver increases and higher as the temperature resulting from the heat generation of the data driver decreases.

The first voltage may be a voltage for compensating each of the plurality of sub-pixels electrically connected to the first reset voltage lines, and may be a reference voltage for compensating all of the sub-pixels of the display panel.

The second voltage may be a voltage for compensating each of the plurality of sub-pixels electrically connected to a predetermined number of additional reset voltage lines disposed in upward, downward, leftward, and rightward directions with respect to the data driver, and the second voltage may be determined based on a temperature due to heat generation of the data driver.

According to one or more embodiments of the invention, a display panel includes: a plurality of pixels; a plurality of data lines configured to supply data voltages to the plurality of pixels; a plurality of gate lines configured to supply gate signals to the plurality of pixels; and a plurality of reset voltage lines to which a reset voltage for initializing light-emitting elements included in the plurality of pixels is applied. A first reset voltage is applied to a plurality of first reset voltage lines among the plurality of reset voltage lines, and a second reset voltage different from the first reset voltage is applied to a plurality of second reset voltage lines among the plurality of reset voltage lines.

The plurality of first reset voltage lines may be disposed in a remaining area of the display panel excluding a peripheral area of a data driver electrically connected to the plurality of data lines, the plurality of second reset voltage lines may be disposed in the peripheral area of the data driver, and the second reset voltage applied through the plurality of second reset voltage lines may be lower than the first reset voltage.

The plurality of second reset voltage lines may include a predetermined number of reset voltage lines disposed above the data driver and a predetermined number of reset voltage lines disposed below the data driver.

According to one or more embodiments of the invention, a display panel includes: a plurality of pixels; a plurality of data lines configured to supply data voltages to the plurality of pixels; a plurality of gate lines configured to supply gate signals to the plurality of pixels; a plurality of reset voltage lines to which a first reset voltage for initializing light-emitting elements included in the plurality of pixels is applied; and a plurality of additional reset voltage lines disposed in a peripheral area of a data driver electrically connected to the plurality of data lines. A second reset voltage for initializing light-emitting elements of sub-pixels disposed in the peripheral area of the data driver is applied to the plurality of additional reset voltage lines.

The plurality of reset voltage lines may be disposed to extend across substantially entire region of the display panel.

The plurality of additional reset voltage lines may be disposed in upward, downward, leftward, and rightward directions of the data driver and include a predetermined number of reset voltage lines.

According to one or more embodiments of the invention, a method for driving a display panel having a plurality of pixels each including a plurality of sub-pixels, a plurality of data lines connected to each of the sub-pixels, and a plurality of reset voltage lines to which a reset voltage for initializing light-emitting elements included in the respective sub-pixels is applied, the method includes: applying a data voltage to each of the sub-pixels through the plurality of data lines; applying a first reset voltage to a plurality of first reset voltage lines among the plurality of reset voltage lines to initialize light-emitting elements of sub-pixels disposed in regions of the display panel excluding a peripheral region of a data driver; and applying a second reset voltage different from the first reset voltage to a plurality of second reset voltage lines disposed in the peripheral region of the data driver. The second reset voltage is lower than the first reset voltage and is determined based on a temperature resulting from heat generation of the data driver.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic plan view illustrating a display device according to an embodiment of the invention.

FIG. 2 is an exemplary plan view illustrating a plurality of reset voltage lines disposed on a display panel according to an embodiment of the invention.

FIG. 3A is a graph illustrating the determination of a reset voltage applied through a plurality of reset voltage lines when a display panel is at a first temperature according to an embodiment of the invention.

FIG. 3B is a graph illustrating the determination of a reset voltage applied through a plurality of reset voltage lines when a display panel is at a second temperature according to an embodiment of the invention.

FIG. 3C is a graph illustrating the determination of a reset voltage applied through a plurality of reset voltage lines when a display panel is at a third temperature according to an embodiment of the invention.

FIG. 4 is an exemplary image illustrating a state in which a luminance change occurs based on temperature in a display panel shown in FIG. 2..

FIG. 5A is an exemplary view illustrating measured temperatures of a data driver for each display panel according to an embodiment of the invention.

FIG. 5B is an exemplary view illustrating luminance sensitivity for each display panel according to an embodiment of the invention.

FIG. 6 is another exemplary plan view illustrating a plurality of reset voltage lines disposed on a display panel.

FIG. 7 is an equivalent circuit diagram of an illustrative pixel circuit within the display panel according to an embodiment of the invention.

FIG. 8A is a timing diagram showing driving waveforms of the display panel to which a first reset voltage is applied according to an embodiment of the invention.

FIG. 8B is a timing diagram showing driving waveforms of the display panel to which a second reset voltage is applied according to an embodiment of the invention.

FIG. 9 is a still another exemplary plan view illustrating a plurality of reset voltage lines disposed on a display panel.

FIG. 10 is an equivalent circuit diagram of an illustrative pixel circuit within the display panel according to another embodiment of the invention.

FIG. 11A is a timing diagram showing driving waveforms of the display panel to which a first reset voltage is applied according to another embodiment of the invention.

FIG. 11B is a timing diagram showing driving waveforms of the display panel to which a second reset voltage is applied according to another embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

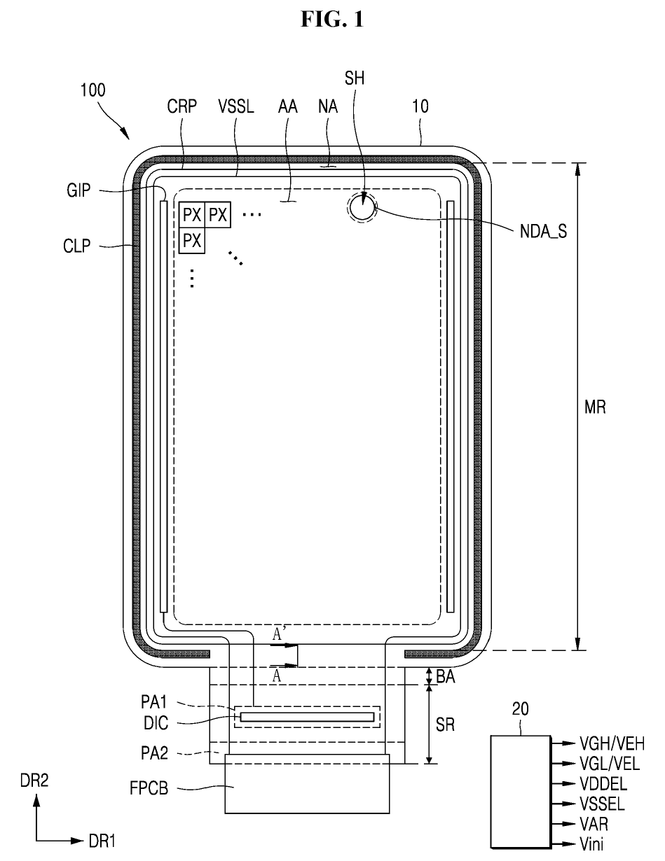

FIG. 1 is a schematic plan view illustrating a display device according to one embodiment of the invention.

Referring to FIG. 1, a display device 100 according to an embodiment of the invention may include a display panel 10.

The display panel 10 may include a plurality of areas. The plurality of areas may include a main area MR, a bending area BA, and a sub-area SR.

The main area MR may include an active area AA and a non-active area NA. The bending area BA may be bent in a thickness direction from the main area MR. The sub-area SR may be connected to the bending area BA and may face the main area MR.

The active area AA may be an area in which an image is displayed. The non-active area NA may be an area other than the active area AA. Although not illustrated, the active area AA may have a pixel array formed therein.

One or more non-active areas NA in which no image is displayed may include a cladding part CLP that serves as a dam and may be provided on one side surface of the active area AA. For example, the non-active area NA may be adjacent to one or more side surfaces of the active area AA. In FIG. 1, a data driver DIC is exemplarily illustrated as being located on the sub-area SR. However, this is merely one embodiment, and the data driver DIC may alternatively be located within the non-active area NA in other embodiments.

The non-active area NA may surround and may be positioned outside the rectangular active area AA. However, it should be understood that shapes of the active area AA and the arrangement of the non-active area NA adjacent to the active area AA are not specifically limited to the exemplary display device 100 illustrated in FIG. 1. The active area AA and the non-active area NA may have any shape of the display device 100. Non-limiting examples of these shapes may include a pentagon, hexagon, circle, oval, and the like, and the embodiments of the invention are not limited thereto.

A crack detection pattern CRP may be disposed in the non-active area NA to surround three sides of the active area AA. The crack detection pattern CRP may be used to detect cracks occurring in the display panel 10.

A low potential power line VSSL may be disposed between the crack detection pattern CRP and the active area AA to surround three sides of the active area AA.

A gate driver GIP may be disposed in the non-active area NA at both sides of the active area AA in a second direction DR2. The gate driver GIP supplies a gate signal (or a scan signal) to the active area AA.

The active area AA may include a second non-active area NDA_S in which a camera area SH is disposed. A camera may be disposed within the camera area SH.

The bending area BA may be disposed between the main area MR and the sub-area SR and may connect the main area MR to the sub-area SR. A width of the bending area BA in a first direction DR1 may be smaller than a width of the main area MR in the first direction DR1 or a width of the sub-area SR in the first direction DR1.

Although not illustrated, the display device 100 may further include a plurality of lines extending from the sub-area SR to the main area MR through the bending area BA. The plurality of lines may include a first line to which a first voltage is applied, a second line to which a second voltage is applied, and a dummy line which is disposed between the first line and the second line and to which a third voltage is applied.

Referring to FIG. 1, the display device 100 may further include the data driver DIC disposed in the sub-area SR, and the first line and the second line may each be connected to the data driver DIC.

The active area AA may include a plurality of pixels PX. One pixel PX may include a plurality of sub-pixels. Each of the plurality of sub-pixels may include a light-emitting element. The light-emitting element may be an inorganic light-emitting element or an organic light-emitting element, and the embodiments of the invention are not limited thereto. The plurality of sub-pixels may display colors such as red (R), green (G), blue (B), white (W), etc. The plurality of sub-pixels are disposed in the active area AA and may each include one or more transistors. At least one transistor may be connected to the light-emitting element.

In addition, each pixel and sub-pixel may be associated with a pixel circuit including one or more TFTs manufactured on the display panel 10 of the display device 100. Each pixel circuit may be electrically connected to a gate line and a data line to communicate with one or more driving circuits, for example, the gate driver GIP and the data driver DIC that are positioned in the non-active area NA of the display device 100.

The sub-area SR may include a first pad area PA1 and a second pad area PA2. For example, as shown in FIG. 1, the data driver DIC may be disposed in the first pad area PA1, and a flexible printed circuit board FPCB may be disposed in the second pad area PA2.

One or more driving circuits may be implemented as TFTs formed within the non-active area NA. For example, the gate driver GIP may be implemented using a plurality of TFTs on the display panel 10 of the display device 100. Non-limiting examples of circuits that may be formed of TFTs of the display panel may include an inverter circuit, a multiplexer, an electrostatic discharge (ESD) circuit, and the like, and the embodiments of the invention are not limited thereto.

Some driving circuits may be provided as integrated circuit (IC) chips and mounted within the non-active area NA of the display device 100 using chip-on-glass COG or other similar methods. In addition, some driving circuits may be mounted on another substrate and coupled to connection interfaces (pads, bumps, pins) disposed within the non-active area NA using a flexible printed circuit board (FPCB), a chip-on-film (COF), a tape-carrier-package (TCP), or other suitable technologies.

In the embodiment, at least two different types of TFTs are used in a TFT substrate for display. The types of TFTs employed in some pixel circuits and some driving circuits may vary depending on the requirements of the display.

For example, the pixel circuit may be implemented using a TFT having an oxide active layer (oxide TFT), and the driving circuit may be implemented using a TFT having a low-temperature polycrystalline silicon active layer (LTPS TFT) and a TFT having an oxide active layer. Unlike LTPS TFTs, oxide TFTs have no threshold voltage (Vth) fluctuations from pixel-to-pixel. A uniform threshold voltage (Vth) may also be acquired in an array of pixel circuits for a display. A threshold voltage (Vth) uniformity issue between TFTs implementing the driver circuit will be less affected by the luminance uniformity of the pixels.

Using the driving circuits on the substrate implemented using LTPS TFTs, signals and pieces of data may be provided to pixels using a higher clock than a case in which all TFTs in the TFT panel are formed as oxide TFTs. Accordingly, a display capable of a high-speed operation may be provided without spots such as Mura or the like. For example, the advantages of oxide TFT and LTPS TFT may be combined with the design of the TFT panel, and oxide TFT and LTPS TFT may be used by being selected according to each advantage.

The power supply unit 20 may supply power necessary for driving each of the plurality of pixels PX. For example, each pixel PX may receive a gate signal from the gate driver GIP through a gate line and a data signal from the data driver DIC through a data line. In addition, each pixel PX may receive a high potential driving voltage VDDEL and a low potential driving voltage VSSEL from the power supply unit 20, but the embodiments of the invention are not limited thereto. In addition, the plurality of pixels PX may additionally include a power line to receive a bias voltage Vobs and initialization voltages VAR and Vini.

The power supply unit 20 may generate DC power required to drive the pixel array of the display panel 10 and a display panel driver using a DC-DC converter. The DC-DC converter may include a charge pump, a regulator, a buck converter, a boost converter, or the like, but the embodiments of the invention are not limited thereto. The power supply unit 20 may receive a DC input voltage applied from a host system and generate DC voltages such as gate-on voltages VGL and VEL, gate-off voltages VGH and VEH, the high potential driving voltage VDDEL, the low potential driving voltage VSSEL, etc. The gate-on voltages VGL and VEL and the gate-off voltages VGH and VEH may be supplied to a level shifter and the gate driver GIP. In addition, the high potential driving voltage VDDEL and the low potential driving voltage VSSEL may be supplied in common to the pixels PX.

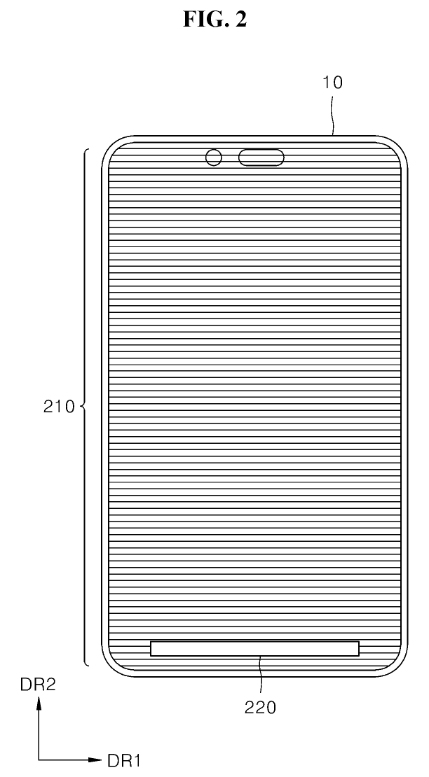

FIG. 2 is an exemplary plan view illustrating a plurality of reset voltage lines disposed on a display panel according to an embodiment of the invention.

Referring to FIG. 2, a plurality of reset voltage lines (VARL) 210 may be disposed on the display panel 10 to extend in the first direction DR1. In addition, the data driver 220 may be disposed on a lower portion of the display panel 10. For example, the data driver 220 may be disposed at a lower side or upper side of the lower portion of the display panel 10. FIG. 2 illustrates the data driver 220 disposed at the lower side of the lower portion of the display panel 10, but in the specification, it is apparent that the data driver 220 may be disposed at an upper side, left side, right side, or central portion of the lower portion of the display panel 10.

The plurality of reset voltage lines (VARL) 210 may be electrically connected to the sub-pixels, respectively, so that a reset voltage for initializing the light-emitting element of each sub-pixel included in each pixel of the display panel 10 is applied. The plurality of reset voltage lines (VARL) 210 may be disposed at regular intervals in the second direction DR2 (i.e., from the upper side to the lower side) of the display panel 10 and may extend in the first direction DR1.

The data driver 220 may be disposed parallel to the first direction DR1 in which the plurality of reset voltage lines (VARL) 210 are disposed.

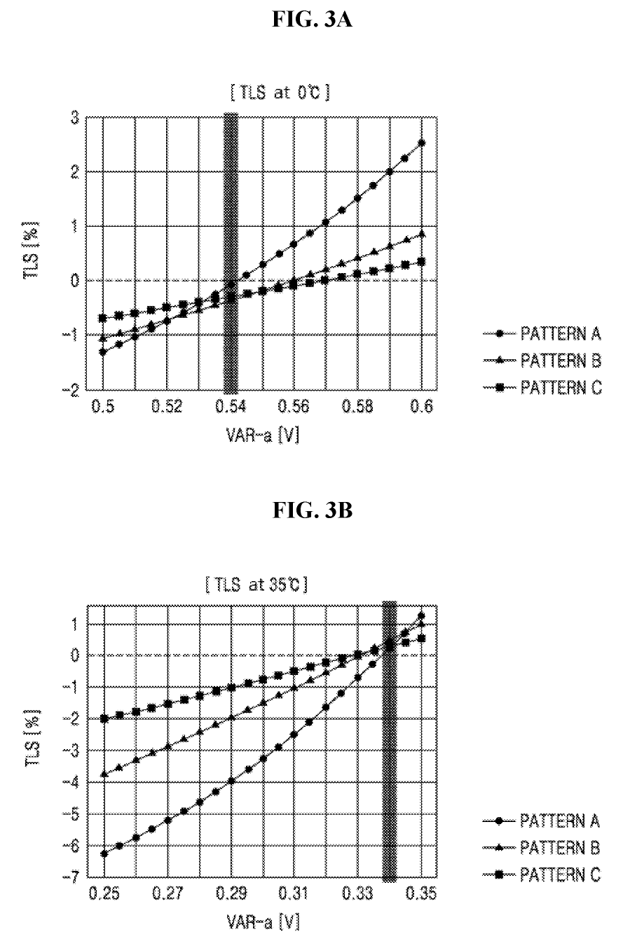

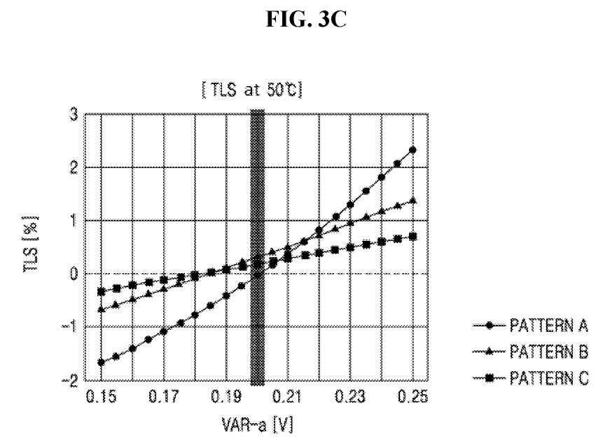

FIG. 3A is a graph illustrating the determination of a reset voltage applied through a plurality of reset voltage lines when a display panel is at a first temperature according to an embodiment of the invention. FIG. 3B is a graph illustrating the determination of a reset voltage applied through a plurality of reset voltage lines when a display panel is at a second temperature according to an embodiment of the invention. FIG. 3C is a graph illustrating the determination of a reset voltage applied through a plurality of reset voltage lines when a display panel is at a third temperature according to an embodiment of the invention.

Referring to FIGS. 3A to 3C, a Y-axis of the graph may represent luminance sensitivity, and an X-axis may represent a reset voltage. Each display panel may have different temperature luminance sensitivity (TLS) characteristics, and the display device 100 may apply a temperature-dependent reset voltage to the display panel 10 through a lookup table in order to compensate for temperature-dependent luminance fluctuations. A reset voltage sweep test (VAR sweep test) may be used to determine an appropriate reset voltage.

Referring to FIG. 3A, when the temperature of the display panel is the first temperature (e.g., 0 °C), the reset voltage is determined based on a TLS value of zero (0) and is about 0.54 V. For example, for each display panel, a pattern with good TLS is selected from a plurality of patterns (e.g., pattern A, pattern B, and pattern C). Referring to FIG. 3A, the reset voltage at which the TLS value becomes zero (0) is about 0.54 V.

Referring to FIG. 3B, when the temperature of the display panel is the second temperature (e.g., 35 °C), the reset voltage is determined based on a TLS value of zero (0) and is about 0.34 V. For example, for each display panel, a pattern with good TLS is selected from a plurality of patterns (e.g., pattern A, pattern B, and pattern C). Referring to FIG. 3B, the reset voltage at which the TLS value becomes zero (0) is about 0.34 V.

Referring to FIG. 3C, when the temperature of the display panel is the third temperature (e.g., 50 °C), the reset voltage is determined based on a TLS value of zero (0) and is about 0.20 V. For example, for each display panel, a pattern with good TLS is selected from a plurality of patterns (e.g., pattern A, pattern B, and pattern C). Referring to FIG. 3C, the reset voltage at which the TLS value becomes zero (0) is about 0.20 V.

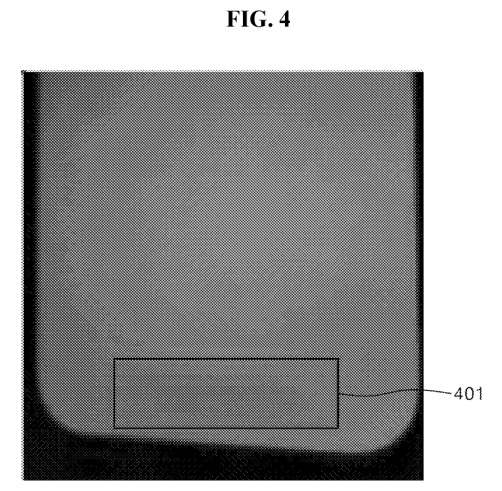

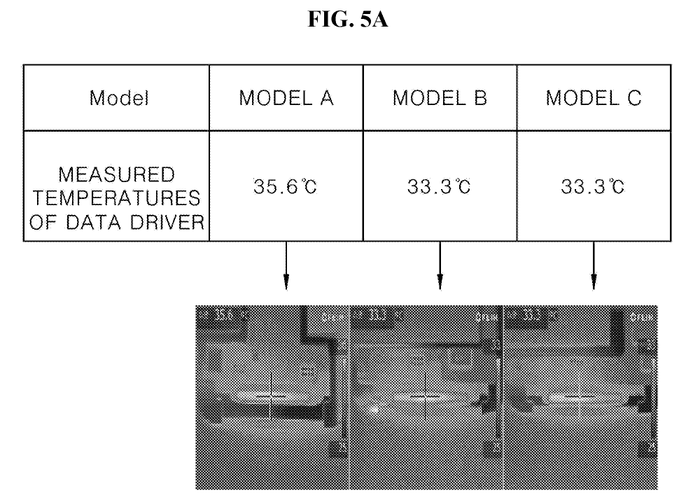

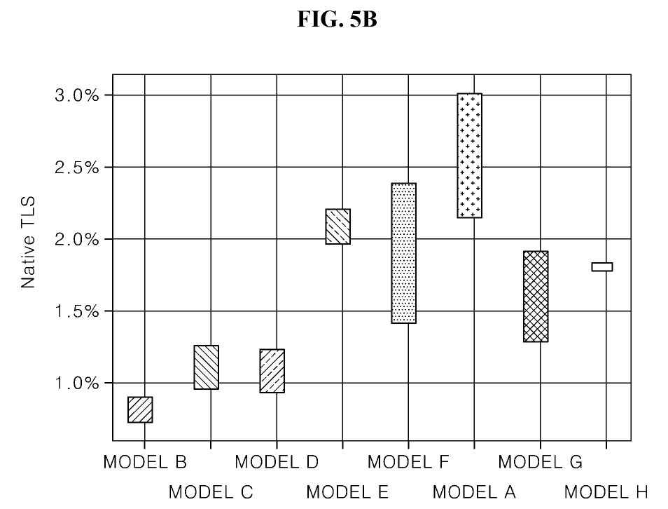

FIG. 4 is an exemplary image illustrating a state in which a luminance change occurs based on temperature in a display panel shown in FIG. 2. FIG. 5A is an exemplary view illustrating measured temperatures of a data driver for each display panel according to an embodiment of the invention. FIG. 5B is an exemplary view illustrating luminance sensitivity for each display panel according to an embodiment of the invention.

FIG. 4 shows a state in which luminance changes due to temperature occur in the display panel.

The compensation for the TLS characteristics is performed over the entire display panel based on measured values of a predetermined area in a central portion of the display panel.

However, as illustrated in FIG. 2, when the data driver is disposed at a lower portion of the panel, referring to FIG. 4, a peripheral area 401 of the data driver 220 may be hotter than other areas (i.e., areas excluding the peripheral area 401 of the display panel) due to heat generated by the data driver 220, and for this reason, compensation may not be performed on the peripheral area 401 of the data driver 220.

Referring to FIG. 5A, a center temperature of the data driver may be 35.6 °C when the display panel is Model A, the center temperature of the data driver may be 33.3 °C when the display panel is Model B, and the center temperature of the data driver may be 33.3 °C when the display panel is Model C.

Referring to FIG. 5B, the TLS for each display panel may be different. For example, it can be seen that Model A has the highest TLS, about 2.1% to 3%, and Model B has the lowest TLS, about 0.3% to 0.8%.

In this way, due to heat generation resulting from the operation of the data driver, which is typically disposed on the lower portion of the display panel, the temperature of the peripheral area of the data driver may be higher than that of other areas, and consequently, compensation needs to be performed with a voltage different from, for example, lower than, the compensation voltages of the sub-pixels positioned in other areas.

In this way, since the TLS for each display panel is different, an appropriate reset voltage needs to be provided to the display panel in order to compensate for the temperature-dependent luminance fluctuations.

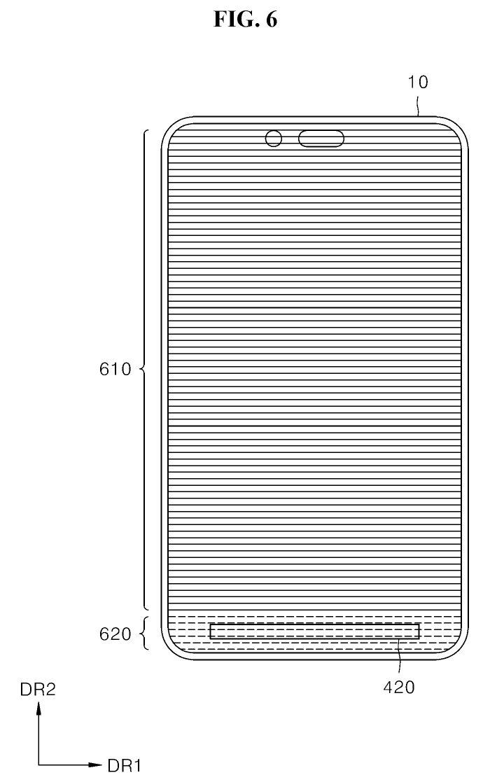

FIG. 6 is another exemplary plan view illustrating a plurality of reset voltage lines disposed on a display panel.

Referring to FIG. 6, among the plurality of reset voltage lines (VARL), a plurality of first reset voltage lines 610 and a plurality of second reset voltage lines 620 may be disposed on the display panel 10 in the first direction DR1. In addition, the data driver 220 may be disposed on a lower portion of the display panel 10. For example, the data driver 220 may be disposed at a lower side or upper side of the lower portion of the display panel 10. FIG. 6 illustrates the data driver 220 disposed at the lower side of the lower portion of the display panel 10, but in the specification, it is apparent that the data driver 220 may be disposed at an upper side, left side, right side, or central portion of the lower portion of the display panel 10.

The plurality of reset voltage lines (VARL) may be electrically connected to the sub-pixels, respectively, so that the reset voltage for initializing the light-emitting element of each sub-pixel included in each pixel of the display panel 10 is applied. The plurality of reset voltage lines (VARL) may be disposed at regular intervals in the second direction DR2 (i.e., from the upper side to the lower side) of the display panel 10 and may extend in the first direction DR1.

The display panel 10 may include a plurality of pixels. In addition, each pixel may include a plurality of sub-pixels. In addition, the display panel 10 may include data lines connected to each sub-pixel and the plurality of reset voltage lines to which the reset voltage for initializing light-emitting elements included in each of the plurality of sub-pixels is applied.

Among the plurality of reset voltage lines (VARL), the plurality of first reset voltage lines 610 may be disposed in the remaining area of the display panel 10 excluding the peripheral area of the data driver 220, and among the plurality of reset voltage lines (VARL), the plurality of second reset voltage lines 620 may be disposed around the data driver 220 on the display panel 10. In addition, the second voltage (e.g., 0.3 V) applied through the plurality of second reset voltage lines 620 may be a voltage lower than the first voltage (e.g., 0.5 V) applied to the plurality of first reset voltage lines 610.

The first voltage is a voltage for compensating for each of the plurality of sub-pixels electrically connected to the plurality of first reset voltage lines and is a voltage for compensating for the entire display panel 10. In addition, the second voltage (e.g., 0.3 V) may decrease as the temperature due to heat generation of the data driver 220 increases and increase as the temperature due to heat generation of the data driver 220 decreases.

Among the plurality of reset voltage lines, the plurality of second reset voltage lines 620 may be disposed on the display panel 10 so that the second voltage different from the first voltage applied to the plurality of first reset voltage lines 610 among the plurality of reset voltage lines is applied.

The first voltage (e.g., 0.5 V) is a voltage for compensating for each of the plurality of sub-pixels electrically connected to the first reset voltage lines and is a voltage for compensating for the entire display panel 10.

In this way, the plurality of second reset voltage lines may include a predetermined number (e.g., 20) of reset voltage lines disposed upward from the data driver 220 and a predetermined number (e.g., 20) of reset voltage lines disposed downward from the data driver 220. The predetermined number (e.g., 20) may be variably adjusted depending on the heat generation temperature of the data driver 220. For example, as the heat generation temperature of the data driver 220 increases, the predetermined number (e.g., 20) may increase, and as the heat generation temperature of the data driver 220 decreases, the predetermined number (e.g., 20) may decrease.

The plurality of second reset voltage lines 620 may be disposed to extend across the entire display panel 10 in the first direction DR1, and the plurality of first reset voltage lines 10 may be disposed to extend across the entire display panel 10 in the first direction DR1.

The data driver 220 may be disposed parallel to the first direction DR1 in which a plurality of first reset voltage lines (VARL) 610 are disposed.

As described above, the display device 100 may compensate for luminance fluctuations of the plurality of sub-pixels electrically connected to the first reset voltage lines 610, respectively, by applying a reset voltage having the magnitude of the first voltage to the plurality of first reset voltage lines 610.

In addition, the display device 100 may compensate for luminance fluctuations of the plurality of sub-pixels electrically connected to the second reset voltage lines 620, respectively, by applying a reset voltage having the magnitude of the second voltage to the plurality of second reset voltage lines 620 according to the heating temperature of the data driver 220.

In this way, the display device 100 according to the invention may compensate for luminance fluctuations according to the heat generation temperature of the data driver 220 by applying reset voltages having different voltages to the plurality of first reset voltage lines 610 and the plurality of second reset voltage lines 620.

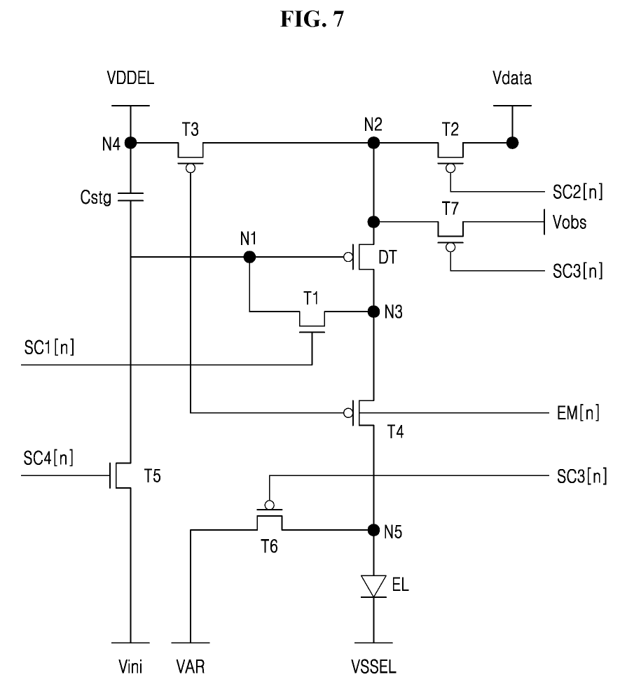

FIG. 7 is an equivalent circuit diagram of an illustrative pixel circuit within the display panel according to an embodiment of the invention.

FIG. 7 illustrates the pixel circuit only for description, and the embodiments of the invention are not limited thereto as long as the pixel circuit has a structure that may control the emission of the light-emitting element EL by receiving an emission signal EM. For example, the pixel circuit may include an additional scan signal, a switching thin film transistor connected to the additional scan signal, and a switching thin film transistor to which an additional initialization voltage is applied, and a connection relationship between the switching elements or a connection position of a capacitor may also be diverse. For convenience of description, the display device having the pixel circuit structure of FIG. 7 will be described below, but the embodiments of the invention are not limited thereto.

Referring to FIG. 7, each of the plurality of pixels PX according to one embodiment of the invention may include a pixel circuit having a driving transistor DT and a light-emitting element EL connected to the pixel circuit, but the embodiments of the invention are not limited thereto.

The pixel circuit may drive the light-emitting element EL by controlling a driving current flowing through the light-emitting element EL. The pixel circuit may include the driving transistor DT, first to seventh transistors T1 to T7, and a capacitor Cstg. Each of the transistors DT and T1 to T7 may include a first electrode, a second electrode, and a gate electrode. One of the first electrode and the second electrode may be a source electrode, and the other may be a drain electrode.

Each of the transistors DT and T1 to T7 may be a P-type thin film transistor or an N-type thin film transistor. In the embodiment of FIG. 7, the first transistor T1 and the fifth transistor T5 are the N-type thin film transistors, and the remaining transistors DT and T2, T3, T4, T6, and T7 are the P-type thin film transistors. However, the inventive concepts are not limited thereto, and in other embodiments, all or some of the transistors DT and T1 to T7 may be formed as the P-type thin film transistors or the N-type thin film transistors. In addition, the N-type thin film transistor may be an oxide thin film transistor, and the P-type thin film transistor may be a polycrystalline silicon thin film transistor. For example, one of the transistors DT and T1 to T7 may be formed of one of an oxide transistor and an LTPS transistor or a combination thereof.

Hereinafter, a case in which the first transistor T1 and the fifth transistor T5 are the N-type thin film transistors, and the remaining transistors DT and T2 T3, T4, T6, and T7 are the P-type thin film transistors will be described, but the embodiments of the invention are not limited thereto. Accordingly, the first transistor T1 and the fifth transistor T5 may be turned on when a high voltage is applied, and the remaining transistors DT and T2, T3, T4, T6, and T7 may be turned on when a low voltage is applied.

The first transistor T1 constituting the pixel circuit may serve as a compensation transistor, the second transistor T2 may serve as a data supply transistor, the third and fourth transistors T3 and T4 may serve as emission control transistors, the seventh transistor T7 may serve as a bias transistor, and the fifth and sixth transistors T5 and T6 may serve as initialization transistors, but the embodiments of the invention are not limited thereto. In addition, a sixth transistor T6 may serve as a reset transistor for resetting the anode electrode of the light-emitting element EL among the initialization transistors, but the embodiments of the invention are not limited thereto.

The light-emitting element EL may include a first electrode and a second electrode. The first electrode of the light-emitting element EL may be an anode electrode, and the second electrode of the light-emitting element EL may be a cathode electrode. The anode electrode of the light-emitting element EL may be connected to a fifth node N5, and the cathode electrode thereof may be connected to the low potential driving voltage VSSEL.

The driving transistor DT may include a second electrode connected to a third node N3, a first electrode connected to a second node N2, and a gate electrode connected to a first node N1. The driving transistor DT may provide a driving current Id to the light-emitting element EL based on a voltage (or a data voltage stored in the capacitor Cstg to be described below) of the first node N1. For example, the driving transistor DT may be connected between the third node N3 and the second node N2.

The first transistor T1 may include a first electrode connected to the third node N3, a second electrode connected to the other electrode (or a second electrode) of the eighth transistor T8, and a first gate electrode receiving a first scan signal SC1[n]. The first transistor T1 may be turned on in response to the first scan signal SC1[n] and diode-connected between the first node N1 and the third node N3 to sample a threshold voltage (Vth) of the driving transistor DT. The first transistor T1 may be a compensation transistor, but the embodiments of the invention are not limited thereto. For example, the first transistor T1 may be connected between the third node N3 and the first node N1. According to one embodiment, the capacitor Cstg may be connected or formed between the first node N1 and a fourth node N4. The capacitor Cstg may store or maintain the provided high potential driving voltage VDDEL.

The second transistor T2 may include a first electrode connected to the data line DL (or receiving the data voltage Vdata), a second electrode connected to the second node N2, and a second gate electrode receiving a second scan signal SC2[n]. The second transistor T2 may be turned on in response to the second scan signal SC2[n] and may transmit the data voltage Vdata to the second node N2. The second transistor T2 may be a data supply transistor, but the embodiments of the invention are not limited thereto. The second transistor T2 may be connected between the data line and the second node N2.

The third transistor T3 and the fourth transistor T4 (or first and second emission control transistors) may be connected between the high potential driving voltage VDDEL and the light-emitting element EL and may form a current flow path through which the driving current Id generated by the driving transistor DT flows.

The third transistor T3 may include a first electrode which is connected to the fourth node N4 and receives the high potential driving voltage VDDEL, a second electrode connected to the second node N2, and a third electrode which receives the emission control signal EM[n]. The third transistor T3 may be connected between the fourth node N4 and the second node N2.

The fourth transistor T4 may include a first electrode connected to the third node N3, a second electrode connected to the fifth node N5 (or the anode electrode of the light-emitting element EL), and a fourth gate electrode which receives the emission control signal EM[n]. The fourth transistor T4 may be connected between the third node N3 and the fifth node N5.

The third and fourth transistors T3 and T4 may be turned on in response to the emission control signal EM[n], a driving current may be provided to the light-emitting element EL, and the light-emitting element EL may emit light with a luminance corresponding to the driving current Id.

The seventh transistor T7may include a first electrode which receives a bias voltage Vobs, a second electrode connected to the second node N2, and a seventh gate electrode which receives a third scan signal SC3[n]. The seventh transistor T7 may be a bias transistor. The seventh transistor T7 may be connected between a bias voltage line and the second node N2.

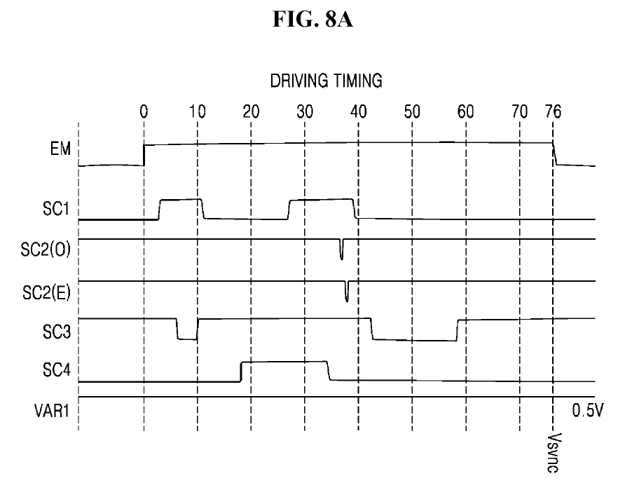

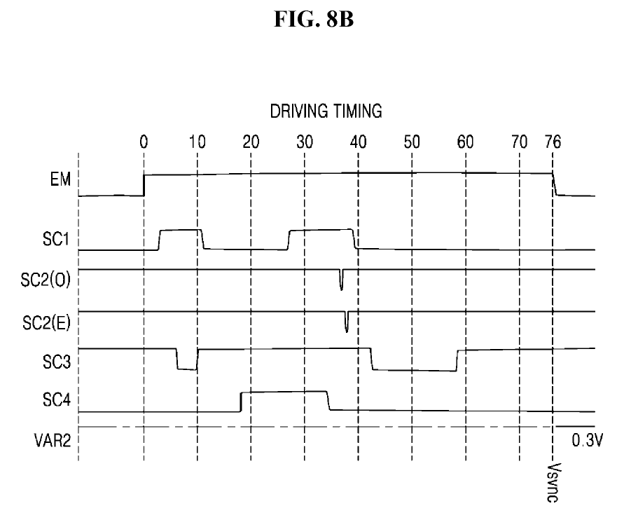

The sixth transistor T6 may include a first electrode which receives a reset voltage VAR, a second electrode connected to the fifth node N5, and a sixth gate electrode which receives the third scan signal SC3[n]. The first electrode of the sixth transistor T6 may be connected to the reset voltage line. The sixth transistor T6 may be connected between the reset voltage line VAR and the fifth node N5. For example, referring to the embodiment illustrated in FIG. 6, the reset voltage lines may include a plurality of first reset voltage lines 610 disposed in regions of the display panel 10 other than the periphery of the data driver 220, and a plurality of second reset voltage lines 620 disposed around the periphery of the data driver 220 in the display panel 10. In addition, the reset voltage VAR applied through the reset voltage lines may include a first reset voltage (VAR1 of FIG. 8A, e.g., 0.5 V) applied to the plurality of first reset voltage lines 610 and a second reset voltage (VAR2 of FIG. 8B, e.g., 0.3 V) applied through the plurality of second reset voltage lines 620.

The sixth transistor T6 may be turned on in response to the third scan signal SC3[n] before the light-emitting element EL emits light (or after the light-emitting element EL emits light) and may initialize the anode electrode (or the pixel electrode) of the light-emitting element EL using the reset voltage VAR. The light-emitting element EL may have a parasitic capacitor formed between the anode electrode and the cathode electrode. In addition, while the light-emitting element EL emits light, the parasitic capacitor may be charged so that the anode electrode of the light-emitting element EL may have a specific voltage. Accordingly, the amount of charges accumulated in the light-emitting element EL may be initialized by applying the reset voltage VAR to the anode electrode of the light-emitting element EL through the sixth transistor T6.

In the embodiment, the gate electrodes of the sixth and seventh transistors T6 and T7 are formed to commonly receive the third scan signal SC3[n]. However, the embodiments are not necessarily limited thereto, and the gate electrodes of the sixth and seventh transistors T6 and T7 may be formed to be independently controlled by receiving separate scan signals.

The fifth transistor T5may include a first electrode which receives the initialization voltage Vini, a second electrode connected to the first node N1, and a gate electrode for receiving a fourth scan signal SC4[n]. The fifth transistor T5 may be connected between the initialization voltage line and the first node N1.

The fifth transistor T5 may be turned on in response to the fourth scan signal SC4[n] and initialize the gate electrode of the driving transistor DT using the initialization voltage Vini. Unnecessary charges may remain in the gate electrode of the driving transistor DT due to the high potential driving voltage VDDEL stored in the capacitor Cstg. Accordingly, the amount of the remaining charges may be initialized by applying the initialization voltage Vini to the gate electrode of the driving transistor DT through the fifth transistor T5.

FIG. 8A is a timing diagram showing driving waveforms of the display panel to which a first reset voltage VAR1 is applied according to an embodiment of the invention. FIG. 8B is a timing diagram showing driving waveforms of the display panel to which a second reset voltage VAR2 is applied according to an embodiment of the invention.

Referring to FIGS. 7 and 8B, the display panel 10 refreshes the image of the display panel in a refresh frame. The display panel 10 applies the initialization voltage Vini to the first node N1 of the pixel circuit during the initialization time of the refresh frame, thereby initializing the first node N1 to the initialization voltage Vini.

During the initialization time of the refresh frame, the first transistor T1 may connect the gate electrode and the drain electrode of the driving transistor DT in response to the first scan signal SC1[n], and the fifth transistor T5 may initialize the storage capacitor Cstg and the gate electrode of the driving transistor DT in response to the fourth scan signal SC4[n].

During the sampling time of the refresh frame, the display panel 10 may transmit the data voltage Vdata to the first node N1 and sample the data voltage Vdata through the storage capacitor Cstg.

During the stress time of the refresh frame, the display panel 10 may apply the on-bias stress voltage Vobs to the first node N1 and apply the anode reset voltage VAR to the anode electrode of the light emitting element EL. In the embodiment, the anode reset voltage VAR may also be referred to as an initialization voltage VAR.

During the sampling time of the refresh frame, the second transistor T2 applies the data voltage Vdata to the source electrode of the driving transistor DT in response to a second scan signal SC2[n]. In this case, the driving transistor DT is turned on by the first initialization voltage Vini transmitted during the initialization time and transmits the data voltage Vdata to the first transistor T1. The first transistor T1 may transmit the data voltage Vdata to the storage capacitor Cstg in response to the first scan signal SC1[n]. The storage capacitor Cstg may sample the data voltage Vdata transmitted from the first transistor T1.

The third scan signal SC3 may be enabled during the initialization time, stress time, and anode reset frame of the refresh frame.

In this case, the display device 100 may adjust at least one of a pulse width or toggle timing of the third scan signal SC3[n] according to a driving frequency or luminance band.

During the stress time of the refresh frame, the sixth transistor T6 initializes the anode electrode of the light-emitting element EL with the reset voltage VAR in response to the third scan signal SC3[n]. The seventh transistor T7 may apply the on-bias stress voltage Vobs to the source electrode of the driving transistor DT in response to the third scan signal SC3[n].

The sixth transistor T6 and the seventh transistor T7 of the pixel circuit may apply a first reset voltage VAR1 to the anode electrode of the light-emitting element EL and apply the on-bias stress voltage Vobs to the source electrode of the driving transistor DT in response to the third scan signal SC3[n] enabled during the initialization time, stress time, and anode reset frame of the refresh frame.

In this case, as illustrated in FIG. 8A, the first reset voltage VAR1 (e.g., 0.5 V) applied to the anode electrode of the light-emitting element EL may be applied to a plurality of sub-pixels disposed on the display panel 10 through the plurality of first reset voltage lines 610 disposed in the remaining area of the display panel 10 excluding the peripheral area of the data driver 220.

In addition, as illustrated in FIG. 8B, a second reset voltage VAR2 (e.g., 0.3 V) applied to the anode electrode of the light-emitting element EL may be applied to the plurality of sub-pixels disposed in the display panel 10 through the plurality of second reset voltage lines 620 disposed around the data driver 220 in the display panel 10.

During the stress time of the refresh frame, the display panel 10 may apply the on-bias stress voltage Vobs to the first node N1 and apply the anode reset voltage VAR to the anode electrode of the light emitting element EL. In the embodiment, the anode reset voltage VAR may be referred to as the initialization voltage VAR.

During the stress time of the refresh frame, the sixth transistor T6 initializes the anode electrode of the light-emitting element EL with the reset voltage VAR in response to the third scan signal SC3[n]. The seventh transistor T7 may apply the on-bias stress voltage Vobs to the source electrode of the driving transistor DT in response to the third scan signal SC3[n].

The display device 100 may include the display panel 10, the data driver 210, and the power supply unit 20. The display panel 10 may include a plurality of pixels, each of which includes a plurality of sub-pixels, data lines connected to each sub-pixel, and a plurality of reset voltage lines to which a reset voltage for initializing light-emitting elements included in each of the plurality of sub-pixels is applied. The data driver 210 may transmit a data voltage to each sub-pixel through the data line. The power supply unit 20 may operate so that the second reset voltage VAR2 different from the first reset voltage VAR1 applied to the plurality of first reset voltage lines among the plurality of reset voltage lines is applied to a plurality of second reset voltage lines among the plurality of reset voltage lines.

The plurality of first reset voltage lines may be disposed in the remaining area of the display panel 10 excluding a peripheral area 930 of the data driver 220. In addition, the plurality of second reset voltage lines may be disposed in the peripheral area 930 of the data driver 220, and the second reset voltage VAR2 applied through the plurality of second reset voltage lines may be a voltage lower than the first reset voltage VAR1.

The first reset voltage VAR1 may be applied to compensate for each of the plurality of sub-pixels electrically connected to the first reset voltage lines and may be applied to compensate for the entire display panel 10.

The second reset voltage VAR2 may be applied to compensate for each of the plurality of sub-pixels electrically connected to the second reset voltage lines and determined based on a temperature due to heat generation of the data driver 220.

The second voltage may decrease as the temperature due to heat generation of the data driver 220 increases, and may increase as the temperature due to heat generation of the data driver 220 decreases.

The plurality of second reset voltage lines may include a predetermined number (e.g., 20) of reset voltage lines disposed upward from the data driver 220 and a predetermined number (e.g., 20) of reset voltage lines disposed downward from the data driver 220.

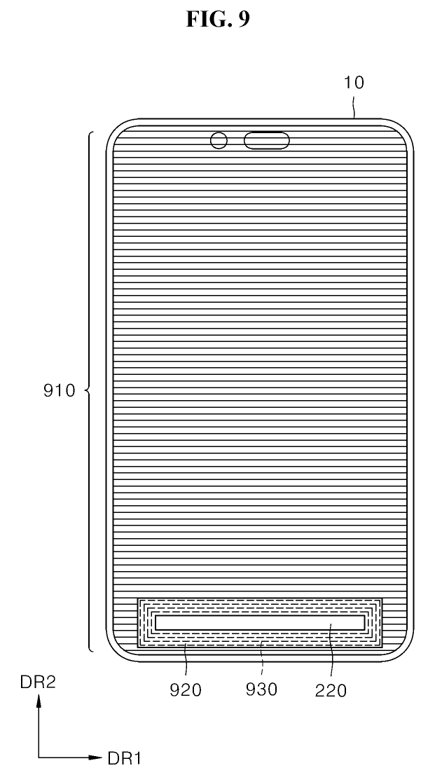

FIG. 9 is a still another exemplary plan view illustrating a plurality of reset voltage lines disposed on a display panel.

Portions that are redundantly described with respect to FIG. 6 may be omitted for convenience of description.

Referring to FIG. 9, a plurality of reset voltage lines 910 may be disposed on the display panel 10 in the first direction DR1. In addition, the data driver 220 may be disposed on a lower portion of the display panel 10. For example, the data driver 220 may be disposed at a lower side or upper side of the lower portion of the display panel 10.

Each of the plurality of reset voltage lines VARL may be disposed at regular intervals in the second direction DR2 of the display panel 10 (i.e., from the upper side to the lower side) and may extend in the first direction DR1.

The plurality of reset voltage lines 910 may be disposed to extend across the entire display panel 10, and a plurality of additional reset voltage lines 920 may be disposed in the peripheral area 930 of the data driver 220 in the display panel 10.

The display panel 10 may further include a plurality of additional reset voltage lines, to which a reset voltage for initializing light-emitting elements included in each of the plurality of sub-pixels disposed around the data driver 220 is applied, in a state in which the plurality of reset voltage lines 910 are disposed to extend across the entire display panel 10.

The plurality of additional reset voltage lines may be disposed on the display panel 10 so that the second voltage different from the first voltage applied to the plurality of reset voltage lines is applied to the plurality of additional reset voltage lines.

For example, the second voltage (e.g., 0.3 V) applied through the plurality of additional reset voltage lines 920 may be a voltage lower than the first voltage (e.g., 0.5 V) applied to a plurality of first reset voltage lines 1110.

The first voltage is a voltage for compensating for each of the plurality of sub-pixels electrically connected to the plurality of first reset voltage lines and is a voltage for compensating for the entire display panel 10.

The second voltage is a voltage for compensating for each of the plurality of sub-pixels electrically connected to a predetermined number of additional reset voltage lines disposed in upward, downward, leftward, and rightward directions of the data driver 220. In addition, the second voltage may be determined based on the temperature due to the heat generation of the data driver 220, and the second voltage may decrease as the temperature due to the heat generation of the data driver 220 increases and increase as the temperature due to the heat generation of the data driver 220 decreases.

The plurality of additional reset voltage lines 920 may be disposed in the upward, downward, leftward, and rightward directions of the data driver 220 and may include a predetermined number of reset voltage lines. The predetermined number may be variably adjusted depending on the heat generation temperature of the data driver 220. For example, as the heat generation temperature of the data driver 220 increases, the predetermined number (e.g., 20) may increase, and as the heat generation temperature of the data driver 220 decreases, the predetermined number (e.g., 20) may decrease. For example, as the heat generation temperature of the data driver 220 increases, the predetermined number (e.g., 20) may increase, and as the heat generation temperature of the data driver 220 decreases, the predetermined number (e.g., 20) may decrease.

The plurality of additional reset voltage lines 920 may be disposed to surround the outer surface of the data driver 220.

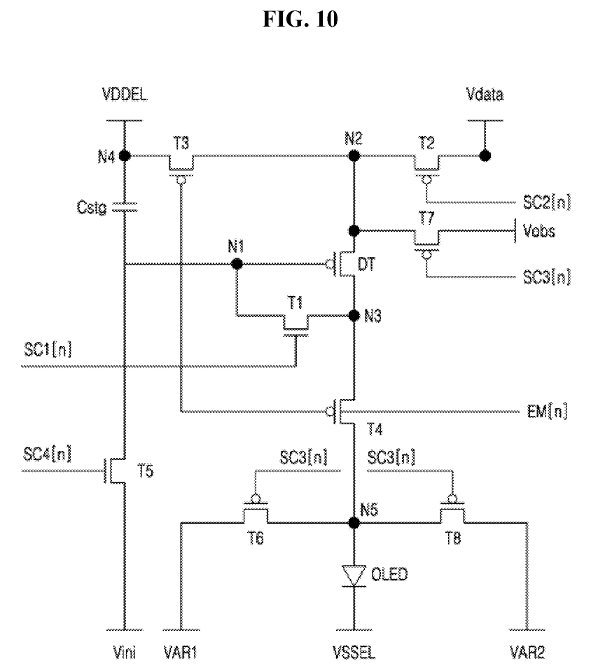

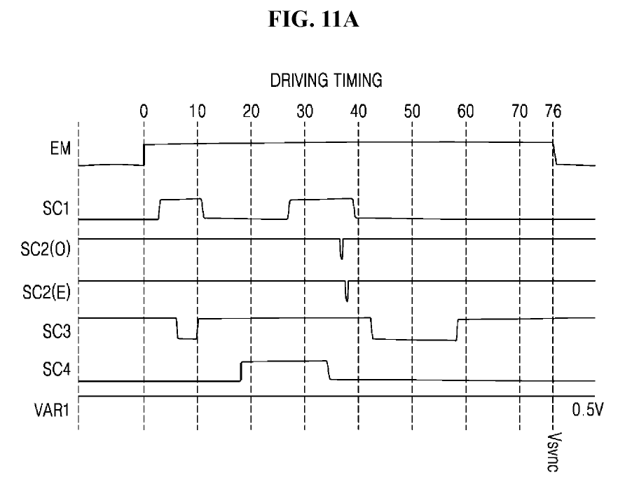

FIG. 10 is an equivalent circuit diagram of an illustrative pixel circuit within the display panel according to another embodiment of the invention.

In the description of FIG. 10, portions that are redundantly described with respect to FIG. 7 are omitted for convenience of description.

Referring to FIG. 10, a pixel circuit may drive the light-emitting element EL by controlling the driving current flowing through the light-emitting element EL. The pixel circuit may include the driving transistor DT, the first to seventh transistors T1 to T7, and the capacitor Cstg. Each of the transistors DT and T1 to T7 may include a first electrode, a second electrode, and a gate electrode. One of the first electrode and the second electrode may be a source electrode, and the other may be a drain electrode.

The driving transistor DT may include a second electrode connected to a third node N3, a first electrode connected to a second node N2, and a gate electrode connected to a first node N1. The driving transistor DT may provide a driving current Id to the light-emitting element EL based on a voltage (or a data voltage stored in the capacitor Cstg to be described below) of the first node N1. For example, the driving transistor DT may be connected between the third node N3 and the second node N2.

The sixth transistor T6 may include the first electrode which receives the first reset voltage VAR1, the second electrode connected to the fifth node N5, and the sixth gate electrode which receives the third scan signal SC3[n]. The first electrode of the sixth transistor T6 may be connected to the reset voltage line. The sixth transistor T6 may be connected between the first reset voltage line and the fifth node N5.

The sixth transistor T6 may be turned on in response to the third scan signal SC3[n] before the light-emitting element EL emits light (or after the light-emitting element EL emits light) and may initialize the anode electrode (or the pixel electrode) of the light-emitting element EL using the first reset voltage VAR1. The light-emitting element EL may have a parasitic capacitor formed between the anode electrode and the cathode electrode. In addition, while the light-emitting element EL emits light, the parasitic capacitor may be charged so that the anode electrode of the light-emitting element EL may have a specific voltage. Accordingly, the amount of charges accumulated in the light-emitting element EL may be initialized by applying the first reset voltage VAR1 to the anode electrode of the light-emitting element EL through the sixth transistor T6.

The eighth transistor T8 may include the first electrode which receives the second reset voltage VAR2, the second electrode connected to the fifth node N5, and the eighth gate electrode which receives the third scan signal SC3[n]. The first electrode of the eighth transistor T8 may be connected to the reset voltage line. The eighth transistor T8 may be connected between the first reset voltage line and the fifth node N5.

The eighth transistor T8 may be turned on in response to the third scan signal SC3[n] before the light-emitting element EL emits light (or after the light-emitting element EL emits light) and may initialize the anode electrode (or the pixel electrode) of the light-emitting element EL using the second reset voltage VAR2. The light-emitting element EL may have a parasitic capacitor formed between the anode electrode and the cathode electrode. In addition, while the light-emitting element EL emits light, the parasitic capacitor may be charged so that the anode electrode of the light-emitting element EL may have a specific voltage. Accordingly, the amount of charges accumulated in the light-emitting element EL may be initialized by applying the second reset voltage VAR2 to the anode electrode of the light-emitting element EL through the eighth transistor T8.

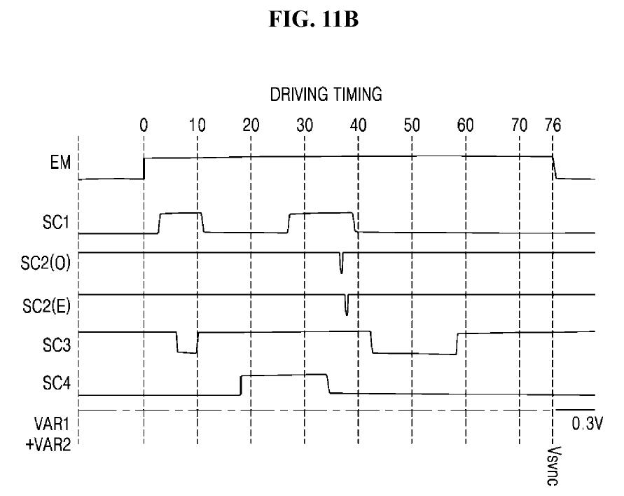

FIG. 11A is a timing diagram showing driving waveforms of the display panel to which a first reset voltage VAR1 is applied according to another embodiment of the invention. FIG. 11B is a timing diagram showing driving waveforms of the display panel to which a second reset voltage VAR2 is applied according to another embodiment of the invention.

In the descriptions of FIGS. 11A and 11B, portions that are redundantly described with respect to FIG. 8A and 8B are omitted for convenience of description.

Referring to FIGS. 10 to 11B, the display panel 10 applies the on-bias stress voltage Vobs to the first node N1 and applies the anode reset voltage VAR to the anode electrode of the light-emitting element EL during the stress time of the refresh frame. In the embodiment, the anode reset voltage VAR may be referred to as the initialization voltage VAR.

During the stress time of the refresh frame, the sixth transistor T6 initializes the anode electrode of the light-emitting element EL with the first reset voltage VAR1 in response to the third scan signal SC3[n]. The seventh transistor T7 may apply the on-bias stress voltage Vobs to the source electrode of the driving transistor DT in response to the third scan signal SC3[n].

During the stress time of the refresh frame, the eighth transistor T8 initializes the anode electrode of the light-emitting element EL with the second reset voltage VAR2 in response to the third scan signal SC3[n]. The seventh transistor T7 may apply the on-bias stress voltage Vobs to the source electrode of the driving transistor DT in response to the third scan signal SC3[n].

In this case, the first reset voltage VAR1 (e.g., 0.5 V) applied to the anode electrode of the light-emitting element EL may be applied to the plurality of sub-pixels disposed on the display panel 10 through the plurality of first reset voltage lines 910 disposed in the remaining area of the display panel 10 excluding the peripheral area of the data driver 220.

In addition, the second reset voltage VAR2 (e.g., 0.3 V) applied to the anode electrode of the light-emitting element EL may be applied to the plurality of sub-pixels disposed in the display panel 10 through the plurality of second reset voltage lines 920 disposed in the peripheral area 930 of the data driver 220 in the display panel 10.

In the embodiment, the anode reset voltage VAR may be referred to as the initialization voltage VAR.

In another embodiment, the display device 100 may include the display panel 10 and the data driver 220. The display panel 10 may include a plurality of pixels, each of which includes a plurality of sub-pixels, data lines connected to each sub-pixel, and a plurality of reset voltage lines to which a first reset voltage VAR1 for initializing light-emitting elements included in each of the plurality of sub-pixels is applied. In addition, the display panel 10 may further include a plurality of additional reset voltage lines to which a second reset voltage VAR2 for initializing the light-emitting elements included in each of the plurality of sub-pixels disposed in the peripheral area of the data driver 220 is applied. In addition, the data driver 220 may transmit the data voltage to each sub-pixel through the data line.

The display device 100 may further include the power supply unit 20 that operates so that the second reset voltage VAR2 different from the first reset voltage VAR1 applied to the plurality of reset voltage lines is applied to the plurality of additional reset voltage lines.

The plurality of reset voltage lines may be disposed in the entire display panel 10, and the plurality of additional reset voltage lines may be additionally disposed around the data driver.

The plurality of additional reset voltage lines may be disposed in the upward, downward, leftward, and rightward directions of the data driver 220 and may include a predetermined number (e.g., 20) of reset voltage lines.

The second reset voltage VAR2 applied through the plurality of additional reset voltage lines may be a voltage lower than the first rest voltage VAR1.

The second reset voltage VAR2 may decrease as the temperature due to heat generation of the data driver 220 increases, and may increase as the temperature due to heat generation of the data driver 220 decreases.

The first reset voltage VAR1 may be applied to compensate for each of a plurality of sub-pixels electrically connected to the plurality of reset voltage lines and may be a reference voltage for compensating all of the sub-pixels of the display panel 10.

The second reset voltage VAR2 is a voltage for compensating for each of the plurality of sub-pixels electrically connected to the predetermined number of the plurality of additional reset voltage lines disposed in the upward, downward, leftward, and rightward directions of the data driver 220 and may be determined based on the temperature due to the heat generation of the data driver 220.

As described above, the display panel 10 may compensate for luminance fluctuations due to the heat generation of the data driver by applying the second reset voltage VAR2 different from the first reset voltage VAR1 applied to the plurality of first reset voltage lines among the plurality of reset voltage lines to the corresponding sub-pixels through the plurality of second reset voltage lines among the plurality of reset voltage lines.

In addition, the display panel 10 may compensate for luminance fluctuations due to the heat generation of the data driver by additionally arranging the plurality of additional reset voltage lines, to which the reset voltage for initializing the light-emitting elements included in each of the plurality of sub-pixels disposed around the data driver, in addition to the plurality of previously disposed reset voltage lines.

According to embodiments of the invention, by varying the magnitude of the reset voltage based on temperature without increasing the number of reset voltage lines applied to the plurality of sub-pixels disposed on the display panel, the display panel can be manufactured without additional costs for preventing luminance fluctuations.

In addition, by applying reset voltages of different magnitudes through the plurality of first reset voltage lines and the plurality of second reset voltage lines among the plurality of reset voltage lines disposed on the display panel, luminance fluctuations due to heat generation of the data driver can be compensated for and potential degradation defect risks can be prevented.

In addition, by arranging the plurality of additional reset voltage lines, in addition to the plurality of reset voltage lines already disposed on the display panel, to which the reset voltages for initializing the light-emitting elements included in each of the plurality of sub-pixels disposed around the data driver, luminance fluctuations due to heat generation of the data driver can be compensated for, thereby improving product reliability.

In addition, by compensating for the sub-pixels disposed in the peripheral area of the data driver being heated with lower voltages, power consumption due to compensation can be reduced.

In addition, by operating the display panel with a lower voltage applied through the reset voltage lines disposed in the peripheral area of the data driver, power consumption can be reduced.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a display panel comprising a plurality of pixels each including a plurality of sub-pixels, a plurality of data lines connected to each of the sub-pixels, and a plurality of reset voltage lines to which a reset voltage for initializing light-emitting elements included in the respective sub-pixels is configured to be applied;
a data driver configured to transmit a data voltage to each of the sub-pixels through the data lines; and
a power supply configured to supply a first reset voltage to a plurality of first reset voltage lines among the plurality of reset voltage lines, and to supply a second reset voltage different from the first reset voltage to a plurality of second reset voltage lines among the plurality of reset voltage lines.

2. The display device of claim 1, wherein:
the plurality of first reset voltage lines are disposed in a remaining area of the display panel excluding a peripheral area of the data driver;
the plurality of second reset voltage lines are disposed in the peripheral area of the data driver; and
the second reset voltage is lower than the first reset voltage.

3. The display device of claim 2, wherein the first reset voltage is a voltage for compensating for each of the plurality of sub-pixels electrically connected to the first reset voltage lines.

4. The display device of claim 2, wherein the second reset voltage is a voltage for compensating for each of the plurality of sub-pixels electrically connected to the second reset voltage lines, and
the second reset voltage is determined based on a temperature resulting from heat generation of the data driver.

5. The display device of claim 4, wherein the second reset voltage decreases as the temperature resulting from heat generation of the data driver increases, and increases as the temperature resulting from the heat generation of the data driver decreases.

6. The display device of claim 1, wherein the plurality of second reset voltage lines include, among the plurality of reset voltage lines, a predetermined number of reset voltage lines disposed above the data driver and a predetermined number of reset voltage lines disposed below the data driver.

7. A display device comprising:
a display panel comprising a plurality of pixels each including a plurality of sub-pixels, a plurality of data lines connected to each of the sub-pixels, and a plurality of reset voltage lines to which a reset voltage for initializing light-emitting elements included in the respective sub-pixels is configured to be applied; and
a data driver configured to transmit a data voltage to each of the sub-pixels through the data lines,
wherein the display panel further includes a plurality of additional reset voltage lines, and a reset voltage is configured to be applied to the plurality of additional reset voltage lines to initialize light-emitting elements of the plurality of sub-pixels disposed in a peripheral area of the data driver.

8. The display device of claim 7, further comprising a power supply circuit configured to apply a first voltage to the plurality of reset voltage lines and apply a second voltage different from the first voltage to the plurality of additional reset voltage lines.

9. The display device of claim 7, wherein the plurality of reset voltage lines are disposed to extend across a substantially entire region of the display panel, and
the plurality of additional reset voltage lines are disposed in the peripheral area of the data driver.

10. The display device of claim 9, wherein the plurality of additional reset voltage lines are disposed in upward, downward, leftward, and rightward directions with respect to the data driver and include a predetermined number of reset voltage lines.

11. The display device of claim 8, wherein the second voltage applied through the plurality of additional reset voltage lines is lower than the first voltage.

12. The display device of claim 11, wherein the second voltage is configured to be lower as the temperature resulting from heat generation of the data driver increases and higher as the temperature resulting from heat generation of the data driver decreases.

13. The display device of claim 8, wherein the first voltage is:
a voltage for compensating each of the plurality of sub-pixels electrically connected to the first reset voltage lines; and
a reference voltage for compensating all of the sub-pixels of the display panel.

14. The display device of claim 8, wherein the second voltage is a voltage for compensating each of the plurality of sub-pixels electrically connected to a predetermined number of additional reset voltage lines disposed in upward, downward, leftward, and rightward directions with respect to the data driver, and
the second voltage is determined based on a temperature due to heat generation of the data driver.

15. A display panel comprising:
a plurality of pixels;
a plurality of data lines configured to supply data voltages to the plurality of pixels;
a plurality of gate lines configured to supply gate signals to the plurality of pixels; and
a plurality of reset voltage lines to which a reset voltage for initializing light-emitting elements included in the plurality of pixels is applied,
wherein a first reset voltage is applied to a plurality of first reset voltage lines among the plurality of reset voltage lines, and
wherein a second reset voltage different from the first reset voltage is applied to a plurality of second reset voltage lines among the plurality of reset voltage lines.

16. The display panel of claim 15, wherein the plurality of first reset voltage lines are disposed in a remaining area of the display panel excluding a peripheral area of a data driver electrically connected to the plurality of data lines,
the plurality of second reset voltage lines are disposed in the peripheral area of the data driver, and
the second reset voltage applied through the plurality of second reset voltage lines is lower than the first reset voltage.

17. The display panel of claim 16, wherein the plurality of second reset voltage lines include a predetermined number of reset voltage lines disposed above the data driver and a predetermined number of reset voltage lines disposed below the data driver.

18. A display panel comprising:
a plurality of pixels;
a plurality of data lines configured to supply data voltages to the plurality of pixels;
a plurality of gate lines configured to supply gate signals to the plurality of pixels;
a plurality of reset voltage lines to which a first reset voltage for initializing light-emitting elements included in the plurality of pixels is applied; and
a plurality of additional reset voltage lines disposed in a peripheral area of a data driver electrically connected to the plurality of data lines,
wherein a second reset voltage for initializing light-emitting elements of sub-pixels disposed in the peripheral area of the data driver is applied to the plurality of additional reset voltage lines.

19. The display panel of claim 18, wherein the plurality of reset voltage lines are disposed to extend across substantially entire region of the display panel.

20. The display panel of claim 18, wherein the plurality of additional reset voltage lines are disposed in upward, downward, leftward, and rightward directions of the data driver and include a predetermined number of reset voltage lines.
